(19) United States
(12) Patent Application Publication
(10) Pub. No.: US 2003/0223204 A1
(43) Pub. Date: Dec. 4, 2003

(54) Electronic apparatus, printed wiring board, and connector fixing method

(75) Inventor: Masatoshi Tandai, Ome-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/405,354

(22) Filed: Apr. 3, 2003

(30) Foreign Application Priority Data
May 31, 2002 (JP) 2002-160683

(51) Int. Cl. H05K 7/10; H05K 7/12

(52) U.S. Cl. 361/767

(57) ABSTRACT

A through hole land to prevent peeling off of a pad is provided at four corners of the pad which is provided on a mounting surface of a printed wiring board. Thereby, the pad is prevented from being peeled off from the printed wiring board by a pry force applied to a lead of a connector, making fixing of the connector firm.

### CROSS-REFERENCE TO RELATED APPLICATIONS

This application is based upon and claims the benefit of priority from the prior Japanese Patent Application No. 2002-160683, filed May 31, 2002.

### BACKGROUND OF THE INVENTION

1. Field of the Invention

The present invention relates to a structure and method of fixing a connector to a printed wiring board, and a printed wiring board to which a connector is fixed. More particularly, the invention relates to a structure and method of fixing various types of interface connectors, such as a power supply input connector including a DC-IN jack, a keyboard connector, a mouse connector, a USB connector, IEEE 1394 connector, a video input connector, a video output connector and an audio jack, to a printed wiring board of an electronic apparatus, and a printed wiring board to which the connector is fixed.

2. Description of the Related Art

In an electronic apparatus such as a portable computer, a DC-IN connector 21 (DC-IN jack) for connecting a power supply plug of a DC adapter, for example, as shown in FIG. 2 is mounted by soldering it to a printed wiring board.

FIG. 11 shows conventional fixing pads 83a, 83b, and 83c for mounting a connector 21 on a printed wiring board 81. FIG. 12 and FIG. 13 are enlarged sectional views of a part at which a fixing lead (a soldering terminal) 91 of the connector 21 is connected to the conventional fixing pad 83. As shown in FIG. 11, provided on the printed wiring board 81 is three fixing pads 83a, 83b and 83c for mounting the connector 21. The pads 83a, 83b and 83c are provided penetrating through the printed wiring board 81 or provided on the mounting surface 82a and backside 82b of the printed wiring board 81.

When mounting the connector 21 on the printed wiring board 81, as shown in FIG. 12, insert a fixing lead 91 of the connector 21 into a hole 84 of each pad 83, and fix the lead to the pads 83a, 83b and 83c with solder 92.

However, in the above-mentioned conventional connector fixing structure, when a pry force is applied to the connector 21 through a power supply plug with the power supply plug inserted into the connector 21, a pry force 93 is applied to the lead 91 of the connector 21, as shown in FIG. 13, and the pad 83 is peeled off from the printed wiring board 81 by this pry force 93. FIG. 13 shows a peeled-off portion 94 formed by the pry force 93 on both sides of the pad 83.

When the pad 83 is peeled off from the printed wiring board 81 as shown above, fixing of the connector 21 is affected, and in the worst case, the connector 21 is separated from the printed wiring board 81.

### BRIEF SUMMARY OF THE INVENTION

The electronic apparatus according to one aspect of the present invention comprises a wiring board; a connector, provided on the wiring board, configured to be connected to an external device and transmit signal between the external device and the electronic apparatus; a pad, provided on the wiring board, configured to be connected to the connector; and a through hole land provided through the pad on the wiring board to fix the pad to the wiring board.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a plan view showing the pattern layout of a printed wiring board according to a first embodiment of the present invention;

FIG. 2 is a perspective view showing the connector mounting state in the first embodiment;

FIG. 3 is a sectional view showing the connector mounting structure in the first embodiment;

FIG. 4 is a plan view showing the pattern layout of the printed wiring board in a second embodiment of the present invention;

FIG. 5 is a perspective view showing the connector mounting state in the second embodiment;

FIG. 6 is a plan view showing the pattern layout of a printed wiring board in a third embodiment of the present invention;

FIG. 7 is a perspective view showing the connector mounting state in the third embodiment;

FIG. 8 to FIG. 10 are plan views showing a modification example of a pad to fix a connector to a printed wiring board;

FIG. 11 is a plan view showing the pattern layout of the connector mounting part of a conventional printed wiring board;

FIG. 12 is a sectional view showing a conventional connector mounting structure; and

FIG. 13 is a sectional view showing the state of peeling off of a fixing pad in a conventional connector mounting structure.

### DETAILED DESCRIPTION OF THE INVENTION

Hereinafter, preferred embodiments of the present invention will be explained with reference to the accompanying drawings.

First, a first embodiment of the present invention will be explained with reference to FIG. 1 to FIG. 3. The first embodiment shows an example of applying the present invention to a DC-IN connector mounting part.

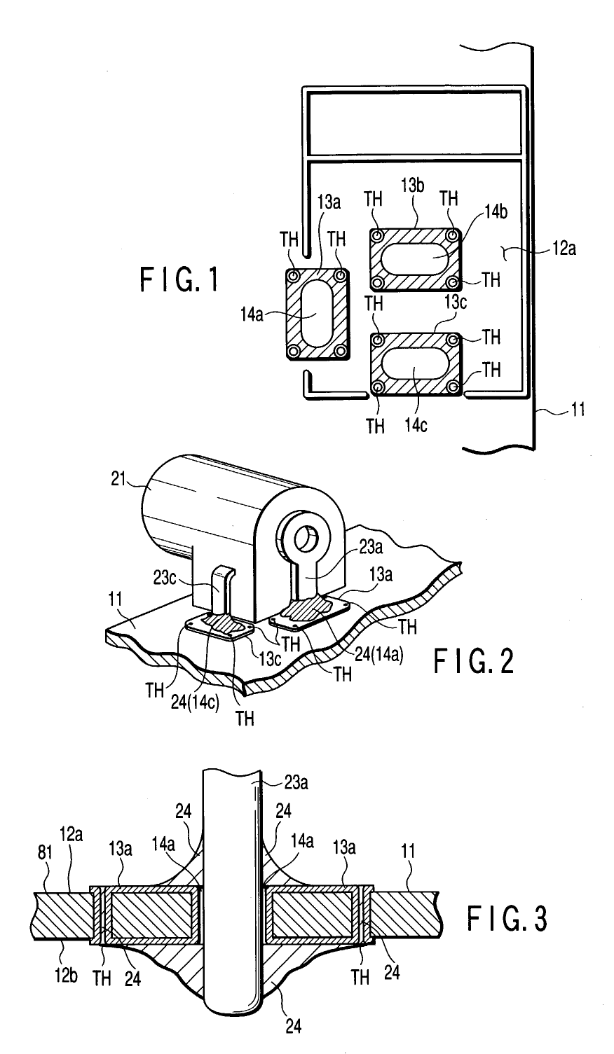

FIG. 1 is a plan view showing the pattern layout of a printed wiring board according to the first embodiment of the present invention. FIG. 2 is a perspective view showing the connector mounting state in the first embodiment. FIG. 3 is a sectional view showing the connector mounting structure in the first embodiment.

As shown in FIG. 1, three substantially rectangular fixing pads 13a, 13b, 13c (hereinafter, generically called a pad 13) for fixing/mounting a DC-IN connector 21 shown in FIG. 2 to/on a printed wiring board 11 are provided on a mounting surface 12a and backside 12b of a printed wiring board 11 (FIG. 3).

At almost the center of each pad 13, elliptical holes. 14a, 14b, 14c (hereinafter generically called a hole 14) for inserting leads 23a, 23b, 23c (soldering terminals) (hereinafter, generically called a lead 23) for fixing the connector 21 are provided penetrating through the printed wiring board 11. For example, each pad 13 is formed by plating a copper foil, and the plated parts of the mounting surface 12a and backside 12b of the printed wiring board 11 are connected through the hole 14.

When mounting the connector 21 on the printed wiring board 11, the lead 23 of the connector 21 is inserted into the hole 14 of each pad 3, and each lead 23 is fixed to the pad 13 with solder 24. Thereby, the connector 21 is fixed to the printed wiring board 11 through the pad 13.

In this embodiment, each pad 13 is firmly fixed to the printed wiring board 13 by providing a through hole land TH at four corners of each pad 13, preventing the pad 13 from being peeled off from the printed wiring board 11 when a pry force is applied to the lead.

The through hole land TH is formed by connecting a part of the mounting side and a part of the backside of the pad 13 through the hole penetrating through the printed wiring board 11. This prevents the pad 13 from being peeled off from the printed wiring board 11, even if a force is applied to the pad 13 in the direction separating from the printed wiring board when a pry force is applied to the lead 23, and the connector 21 is firmly fixed to the printed wiring board 11b.

Namely, when an external deflecting force is applied to the connector 21 through the power supply plug while the power supply plug is being inserted into the connector 21 mounted on the mounting surface 12 of the printed wiring board, a pry force is applied to the lead 23 of the connector 21, and this pry force works in the direction to peel off the pad 13 from the printed wiring board 11. At this time, the through hole land TH provided at four corners of the pad 13 connects the parts of the mounting surface 12a and backside 12b, and the pad 13 is prevented from being peeled off by the pry force stress.

As described above, this embodiment makes it possible to fix the connector 21 to the printed wiring board 11 at a low cost and with a simple structure without using additional parts such as metal fittings for fixing the connector 21 to the printed wiring board 11.

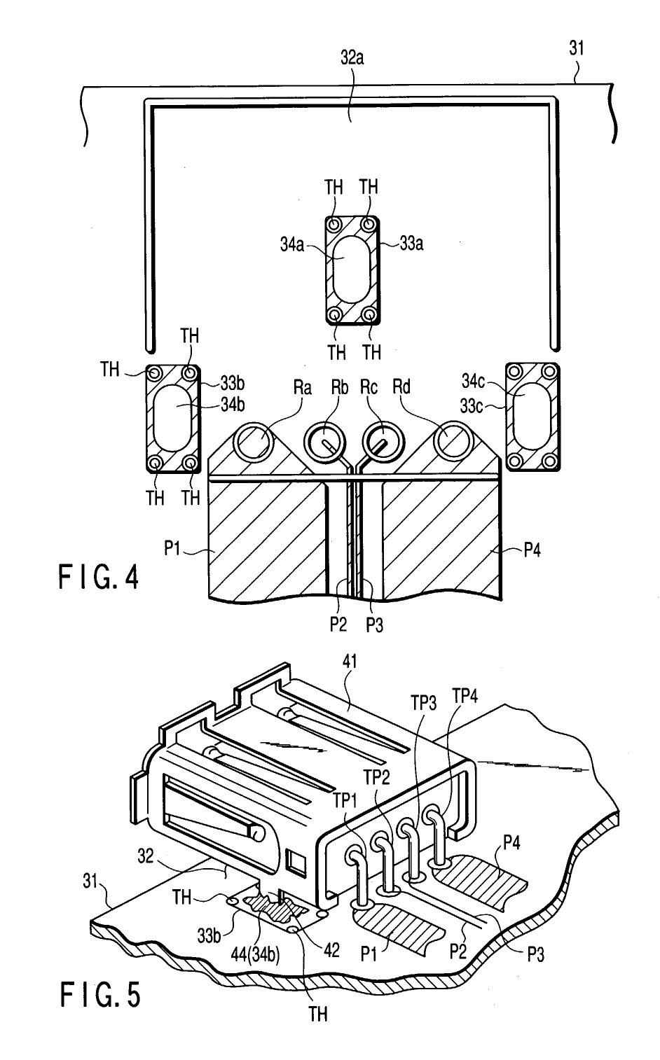

Next, the second embodiment of the present invention will be explained with reference to FIG. 4 and FIG. 5. The second embodiment illustrates an example of applying the present invention to a USB connector mounting part.

FIG. 4 is a plan view showing the pattern layout of the printed wiring board in the second embodiment of the present invention. FIG. 5 is a perspective view showing the connector mounting state in the second embodiment.

As shown in FIG. 4, three substantially rectangular fixing pads 33a, 33b, 33c for fixing/mounting a USB connector 41 shown in FIG. 5 to/on a printed wiring board 31 are provided on the mounting surface 32a and backside 32b (not shown) of the printed wiring board 31.

At almost the center of each pad 33, elliptical holes 34a, 34b, 34c for inserting a lead 42 for fixing the connector 41 are provided penetrating through the printed wiring board 31. Each pad 33 has a through hole land TH at four corners, and fixed firmly to the printed wiring board 31 as in the above-mentioned first embodiment.

On the mounting surface 32a of the printed wiring board 31, four wires P1-P4 for electrically connecting terminals TP1-TP4 of the connector 41 are printed.

When mounting the connector 41 on the printed wiring board 31, insert the lead 42 of the connector 41 into the hole 34 of each pad 33, and fix each lead 42 to the pad 33 with solder 24. Thereby, the connector 41 is fixed to the printed wiring board 31 through the pad 33.

Also in this embodiment, as a through hole land TH is provided at four corners of each pad 33, the same effect as that in the first embodiment can be obtained.

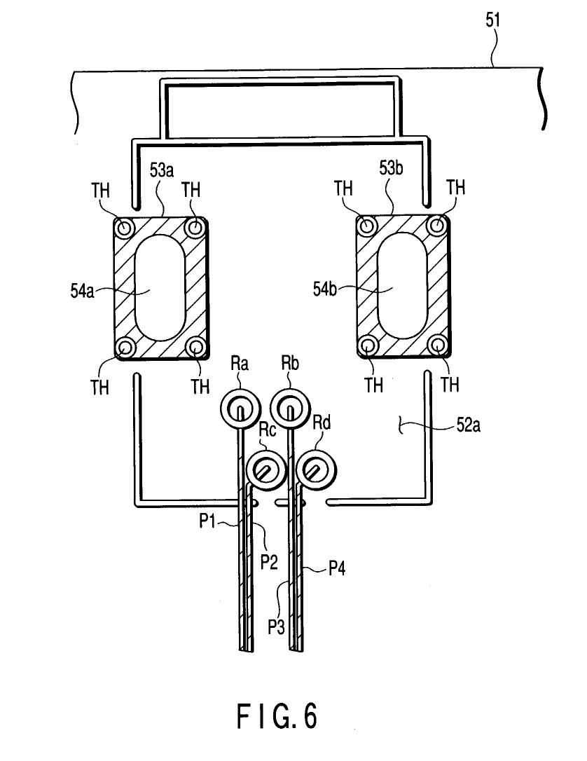

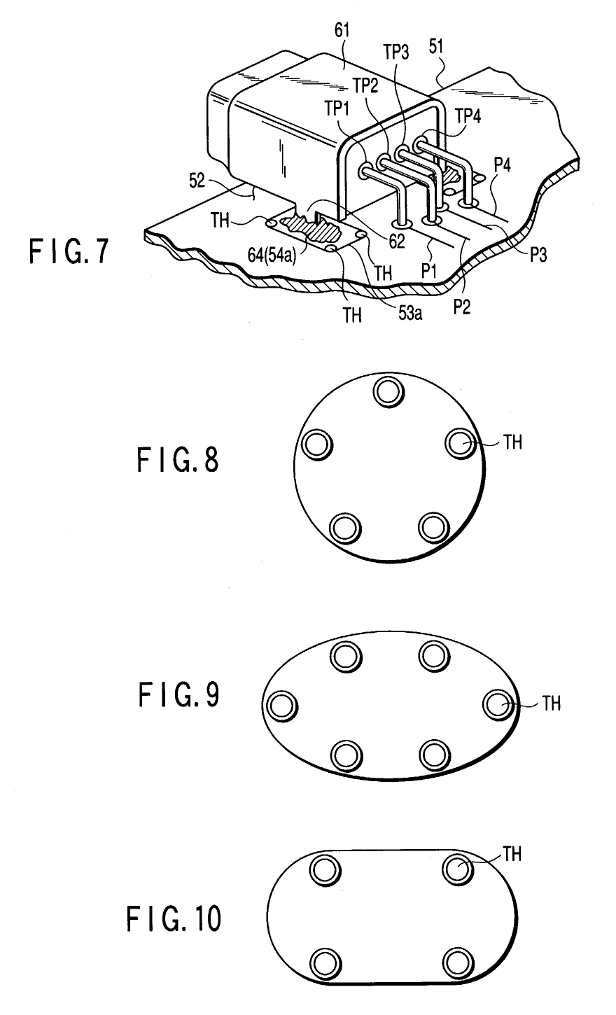

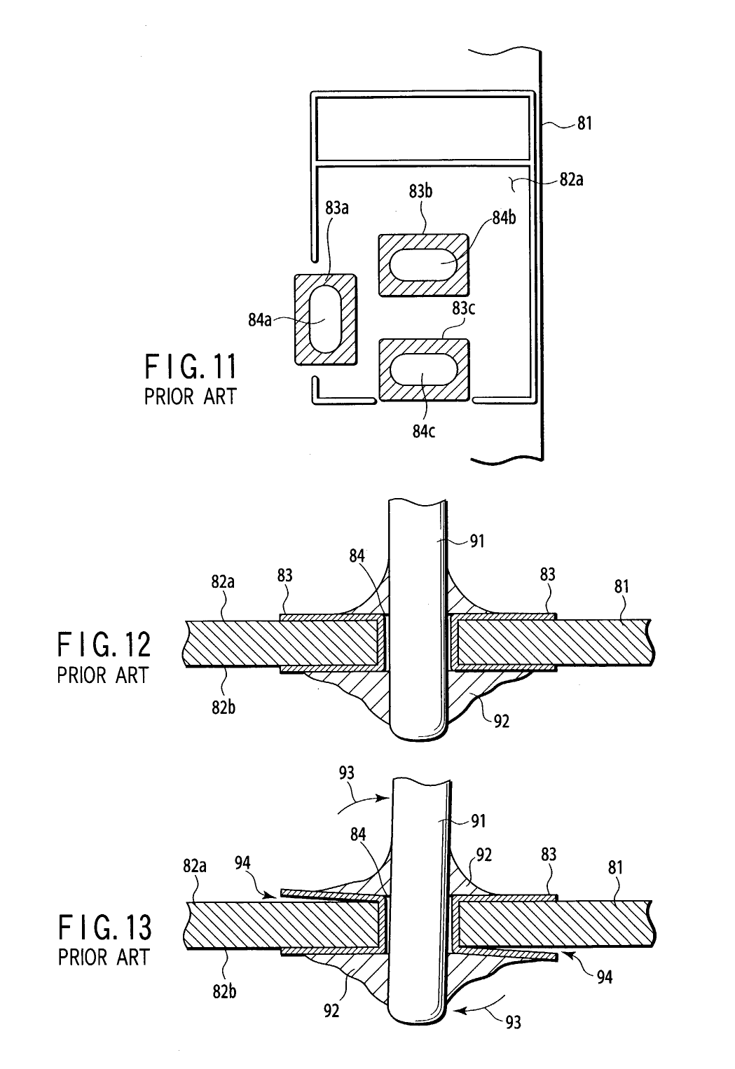

Next, the third embodiment of the present invention will be explained with reference to FIG. 6 and FIG. 7. The third embodiment illustrates an example of applying the present invention to an IEEE 1394 connector mounting part.

FIG. 6 is a plan view showing the pattern layout of a printed wiring board in the third embodiment of the present invention. FIG. 7 is a perspective view showing the connector mounting state in the third embodiment.

As shown in FIG. 6, two substantially rectangular fixing pads 53a and 53b for fixing/mounting an IEEE 1394 connector 61 shown in FIG. 7 to/on a printed wiring board 51 are provided on the mounting surface 52a and backside 52b (not shown) of the printed wiring board 51.

At almost the center of each pad 53, elliptical holes 54a and 54b for inserting a lead 62 for fixing the connector 61 are provided penetrating through the printed wiring board 51. Each pad 53 has a through hole land TH at four corners, and fixed firmly to the printed wiring board 51 as in the above-mentioned first and second embodiments.

On the mounting surface 52a of the printed wiring board 51, four wires P1-P4 for electrically connecting terminals TP1-TP4 of the connector 61 are printed.

When mounting the connector 61 on the printed wiring board 51, insert the lead 62 of the connector 61 into the hole 54 of each pad 53, and fix each lead 62 to the pad 53 with solder 64. Thereby, the connector 61 is fixed to the printed wiring board 51 through the pad 53.

Also in this embodiment, as a through hole land TH is provided at four corners of each pad 53, the same effect as that in the first and second embodiments can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

For example, in the above-mentioned embodiments, the pad for fixing the lead of the connector to the printed wiring board is substantially rectangular, but the pad is not limited to the rectangular form. Circular form as shown in FIG. 8, elliptical form as shown in FIG. 9, or elongate form as shown in FIG. 10 is also permitted. In this case, the same effect of preventing peeling off as that in the above-mentioned embodiments can be obtained by providing a plurality of through hole lands TH at fixed intervals along the edge of a pad. The least necessary number of through hole land is two, and the total number can be optionally set.

Further, in the above-mentioned embodiments, as shown in FIG. 3 for example, the pad can be firmly fixed to the printed wiring board by flowing the solder 24 into the through hole land TH. Namely, as the through hole land TH is formed by plating copper foil so as to connect the mounting surface and the backside through the hole formed penetrating through the printed wiring board, as mentioned above, the land form is cylindrical at the hole. Thus, by filling this cylindrical part with the solder 24, the through hole land TH can be shaped like a bar increasing the strength. Further, it is also possible to connect the solder on the mounting surface and the solder on the backside of the printed wiring board through the solder 24 filled in the through hole land, and the pad can be fixed to the printed wiring board only by soldering.

Moreover, the present invention is applicable not only to the above-mentioned embodiments, but also the structure for fixing various external interface connectors such as a keyboard connector, a mouse connector, a video input connector, a video output connector and an audio jack.

What is claimed is:

1. An electronic apparatus comprising:
a wiring board;
a connector, provided on the wiring board, configured to be connected to an external device and transmit signal between the external device and the electronic apparatus;
a pad, provided on the wiring board, configured to be connected to the connector; and
a through hole land provided through the pad on the wiring board to fix the pad to the wiring board.

2. The electronic apparatus according to claim 1, wherein the through hole land is provided in at least two places of the pad.

3. The electronic apparatus according to claim 2, wherein the through hole land is provided at two or more locations along the edge of the pad.

4. The electronic apparatus according to claim 3, wherein the connector is one of a power supply input connector including a DC-IN jack, a keyboard connector, a mouse connector, a USB connector, an IEEE 1394 connector, a video input connector, a video output connector, and an audio jack.

5. An electronic apparatus comprising:
a wiring board;
a connector, provided on the wring board, configured to be connected to an external device and transmit signal between the external device and the electronic apparatus; and
a pad, provided on the wiring board, configured to be connected to the connector, and having a plurality of through hole lands.

6. The electronic apparatus according to claim 5, wherein the through hole lands are provided in at least two places of the pad.

7. The electronic apparatus according to claim 5, wherein the through hole lands are provided on a corner of the pad.

8. A printed wiring board comprising:
a pad configured to be connected to a connector with solder; and
a through hole land provided through the pad on the wiring board to fix the pad to the wiring board.

9. The printed wiring board according to claim 8, wherein the through hole land provided in at least two places of the pad.

10. A connector fixing method comprising:
fixing at least two places of a pad for fixing a connector to a printed wiring board by a through hole land which reinforces the pad to prevent from being peeled off from the printed wiring board by a pry force applied to the connector, and fixing the connector to the printed wiring board through the pad.

11. The connector fixing method according to claim 10, wherein the through hole land is provided at two or more locations along the edge of the pad.

12. The connector fixing method according to claim 10 or 11, wherein the connector is one of a power supply input connector including a DC-IN jack, a keyboard connector, a mouse connector, a USB connector, an IEEE 1394 connector, a video input connector, a video output connector, and an audio jack.
